(19) United States
(12) Patent Application Publication
(10) Pub. No.: US 2011/0186845 A1
(43) Pub. Date: Aug. 4, 2011

(54) CRYSTALLIZATION METHOD OF AMORPHOUS SEMICONDUCTOR FILM, THIN FILM TRANSISTOR, AND MANUFACTURING METHOD OF THIN FILM TRANSISTOR

(75) Inventors: Kazushi YAMAYOSHI, Tokyo (JP); Kazutoshi Aoki, Kumamoto (JP)

(73) Assignee: MITSUBISHI ELECTRIC CORPORATION, Chiyoda-ku (JP)

(21) Appl. No.: 12/967,683

(22) Filed: Dec. 14, 2010

(30) Foreign Application Priority Data
Feb. 3, 2010 (JP) 2010-022154

(51) Int. Cl. H01L 29/24; H01L 21/84; H01L 21/20

(52) U.S. Cl. 257/59; 438/166; 438/486; 257/E29.101; 257/E21.119; 257/E21.703

(57) ABSTRACT

Provided is a thin film transistor that includes a gate electrode formed in one major plane of a substrate, a gate insulating film covering the gate electrode, a semiconductor film formed opposite to the gate electrode with the gate insulating film interposed and including a first amorphous region to serve as a source region, a second amorphous region to serve as a drain region, and a crystalline region to serve as a channel region disposed between the first amorphous region and the second amorphous region, and a source electrode and a drain electrode formed above the semiconductor film without direct contact with the crystalline region and electrically connected to the source region and the drain region, respectively.

### INCORPORATION BY REFERENCE

This application is based upon and claims the benefit of priority from Japanese patent application No. 2010-22154, filed on Feb. 3, 2010, the disclosure of which is incorporated herein in its entirety by reference.

### BACKGROUND OF THE INVENTION

1. Field of the Invention

The present invention relates to a crystallization method of an amorphous semiconductor film, a thin film transistor, and a manufacturing method of a thin film transistor.

2. Description of Related Art

A liquid crystal display device called a driver circuit integral type in which a driver circuit composed of drive TFTs (Thin Film Transistor) formed simultaneously with a pixel TFT disposed in a pixel is built on the periphery of a pixel part, and a drive IC mounted on the periphery is eliminated is in practical use today. The driver circuit integral type liquid crystal display device is often employed in a small liquid crystal display device or the like.

In the driver circuit integral type liquid crystal display device, for its necessity to achieve a driving speed required for operation of a driver circuit, a polycrystalline silicon TFT with higher driving capability than an amorphous silicon TFT (hereinafter referred to as an amorphous TFT), which has been used for the pixel TFT, is often used as a drive TFT. Further, because it is more advantageous to form the pixel TFT and the drive TFT simultaneously in terms of manufacturing cost, a polycrystalline silicon TFT is often used also as the pixel TFT in accordance with the requirement for the drive TFT.

However, for the pixel TFT, the properties such as high field-effect mobility and low threshold voltage shift of the polycrystalline silicon TFT are unnecessary. Instead, due to non-uniform crystallinity of the polycrystalline silicon TFT, variation of characteristics and leakage current are greater than those when using the amorphous TFT, and display unevenness is caused by using the polycrystalline silicon TFT for the pixel TFT. Therefore it is not always easy to use the polycrystalline silicon TFT for the pixel TFT.

Thus, in order to use the polycrystalline silicon TFT for the pixel TFT in conjunction with using the plycrystalline silicon TFT for the drive TFT, it is required to reduce the variation of characteristics and the leakage current caused by the polycrystalline silicon TFT. A large amount of labor and manufacturing cost have been expended to manufacture a product satisfying this requirement.

On the other hand, as a TFT having the higher field-effect mobility than the amorphous TFT, though not as high as the polycrystalline silicon TFT, a microcrystalline silicon TFT is known (e.g. Japanese Unexamined Patent Application Publication No. 5-55570). The microcrystalline silicon TFT is such that a part of an amorphous semiconductor film of the amorphous TFT is replaced by a microcrystalline semiconductor film. The microcrystalline silicon TFT can be manufactured simply by making a relatively small change to the manufacturing method of the amorphous TFT, and it is expected to be used widely in liquid crystal display devices.

In the microcrystalline silicon TFT, the microcrystalline semiconductor film is formed in a semiconductor film part in the vicinity of the interface with a gate insulating film, which is a path of a current actually flowing during TFT-on. Because a trap density and a defect level due to crystal defect are suppressed in crystalline semiconductor films such as the microcrystalline semiconductor film, TFT characteristics with high field-effect mobility and low threshold voltage shift can be obtained. Further, because the microcrystalline semiconductor film has uniform crystals with a crystal size of 100 nm or less in general, the variation of TFT characteristics can be suppressed.

Note that the microcrystalline semiconductor film may be formed by laser annealing that irradiates an amorphous semiconductor film with laser and allows the laser light to be absorbed into the amorphous semiconductor film for heating, so that it is converted into the microcrystalline semiconductor film. Further, the microcrystalline semiconductor film may be formed directly in a deposition device such as a plasma CVD device, just like the method of forming the amorphous semiconductor film.

However, the microcrystalline silicon TFT has an issue that leakage current (off-current) during TFT-off is high. Therefore, when manufacturing a liquid crystal display device by building the microcrystalline silicon TFT as the pixel TFT in practice, measures to prevent display defect due to the off-current are required. For example, as disclosed in T. Kaitoh, et al., “SELAX Technology for Poly-Si TFTs Integrated with Amorphous-Si TFTs”, SID 08 DIGEST, pp. 1066-1069, it is necessary to design a structure in which the microcrystalline semiconductor film is not in direct contact with a source electrode and a drain electrode, so that the leakage current during TFT-off does not easily flow to the source electrode or the drain electrode. It is known that the leakage current increases significantly under backlight exposure during display.

### SUMMARY OF THE INVENTION

The present invention has been accomplished to address the above issue, and it is desirable to provide a crystallization method of an amorphous semiconductor film which can easily obtain a semiconductor film with favorable characteristics, and a thin film transistor and a manufacturing method of a thin film transistor which apply the same.

A first exemplary aspect of the present invention is a thin film transistor that includes a gate electrode formed in one major plane of a substrate, a gate insulating film covering the gate electrode, a semiconductor film formed opposite to the gate electrode with the gate insulating film interposed and including a first amorphous region to serve as a source region, a second amorphous region to serve as a drain region, and a crystalline region to serve as a channel region disposed between the first amorphous region and the second amorphous region, a source electrode formed above the semiconductor film without direct contact with the crystalline region and electrically connected to the source region, and a drain electrode formed above the semiconductor film without direct contact with the crystalline region and electrically connected to the drain region.

A second exemplary aspect of the present invention is a crystallization method of an amorphous semiconductor film that includes steps of depositing an amorphous semiconductor film in one major plane of a substrate, forming a translucent insulating film of a given shape on the amorphous semiconductor film, and performing laser annealing that irradiates the amorphous semiconductor film with laser light, allowing the laser light to be absorbed into the amorphous semiconductor film through the translucent insulating film, and crystallizing a part of the amorphous semiconductor film under the translucent insulating film.

A third exemplary aspect of the present invention is a manufacturing method of a thin film transistor that includes steps of forming a gate electrode of a given shape in one major plane of a substrate, forming a gate insulating film covering the gate electrode, forming an amorphous first semiconductor film on the gate insulating film, forming a translucent insulating film of a given shape on the first semiconductor film, performing laser annealing that irradiates the first semiconductor film with laser light, allowing the laser light to be absorbed into the first semiconductor film through the translucent insulating film, and crystallizing a part of the first semiconductor film under the translucent insulating film, and patterning the first semiconductor film into a shape including a crystalline region crystallized by the laser annealing and amorphous regions placed opposite to each other with the crystalline region placed therebetween.

According to the exemplary aspects of the present invention described above, it is possible to provide a crystallization method of an amorphous semiconductor film which can easily obtain a semiconductor film with favorable characteristics, and a thin film transistor and a manufacturing method of a thin film transistor which apply the same.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a schematic plan view showing a structure of a liquid crystal display panel used in a liquid crystal display device according to a first exemplary embodiment;

FIG. 2 is a cross-sectional view showing a structure of a microcrystalline TFT according to the first exemplary embodiment;

FIGS. 3A to 3E are cross-sectional views showing a manufacturing process of a microcrystalline TFT according to the first exemplary embodiment;

FIG. 4 is a graph showing a relationship between reflectance of laser light on an amorphous silicon film surface and a thickness of a SiN film;

FIG. 5 is a schematic plan view showing a structure of a mother liquid crystal cell substrate in a manufacturing process of the liquid crystal display device according to the first exemplary embodiment;

FIG. 6 is a plan view showing a liquid crystal display panel of a liquid crystal display device using a typical amorphous TFT used heretofore;

FIG. 7 is a cross-sectional view showing a structure of a microcrystalline TFT according to a second exemplary embodiment; and

FIG. 8 is a cross-sectional view showing a structure of a microcrystalline TFT according to a third exemplary embodiment.

### DESCRIPTION OF THE EXEMPLARY EMBODIMENTS

Exemplary embodiments of the present invention will be described hereinbelow. The following description and the attached drawings are appropriately shortened and simplified to clarify the explanation. Further, the redundant explanation is omitted as appropriate to clarify the explanation. In the figures, the identical reference symbols denote identical structural elements and the redundant explanation thereof are omitted as appropriate.

### First Exemplary Embodiment

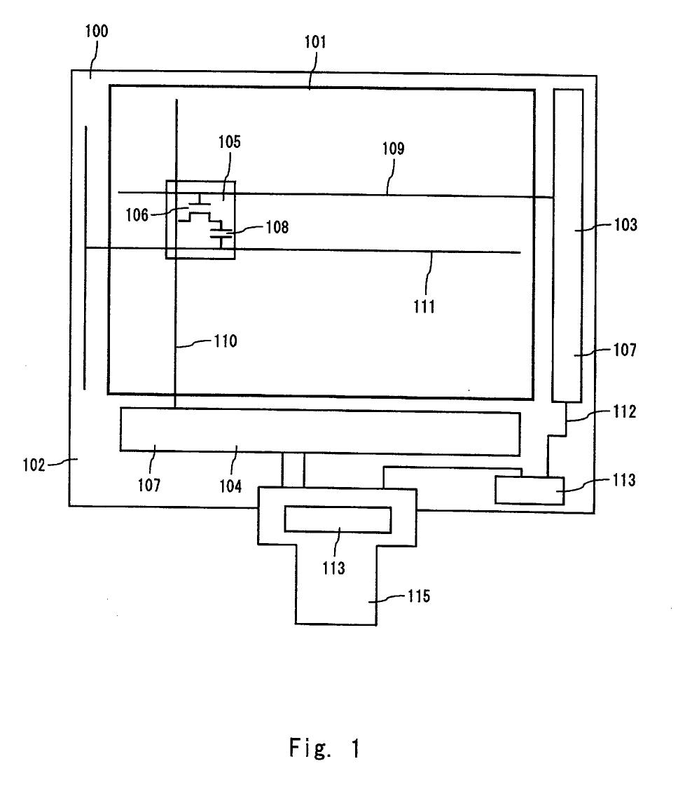

A semiconductor device using a microcrystalline TFT according to a first exemplary embodiment is described firstly with reference to FIG. 1. FIG. 1 is a schematic plan view showing a structure of a liquid crystal display panel used in a liquid crystal display device according to the first exemplary embodiment. Although a liquid crystal display device is described below as an example of the semiconductor device using the microcrystalline TFT according to the first exemplary embodiment, it is just an illustration, and a flat-type display device (flat panel display) such as an organic EL display device or other semiconductor devices may be used. In the first exemplary embodiment, the case where the present invention is applied to a typical liquid crystal display device is described by way of illustration. The overall structure of the liquid crystal display device is common among first to third exemplary embodiments described below. Note that the drawings are illustrated schematically, and they do not show the accurate scale or the like of the elements illustrated therein.

The liquid crystal display device according to the first exemplary embodiment includes a liquid crystal display panel shown in FIG. 1. The liquid crystal display panel has a structure in which two transparent insulating substrates such as glass substrates are placed opposite to each other, and liquid crystals are sealed in a gap surrounded by the substrates and sealing materials for bonding the substrates together. In one substrate, a pixel TFT 106, which is a switching element that controls on and off of supply of a display voltage to be applied to the liquid crystals, is disposed corresponding to a pixel 105, which is a unit of displaying an image as shown in FIG. 1.

Because the pixel TFTs 106 placed in the respective pixels 105 are arranged in an array on the substrate, the substrate on which the pixel TFTs 106 are disposed is called an array substrate 100. The array substrate 100 includes a display area 101 for displaying an image and a frame area 102 surrounding the display area 101. In the display area 101, a plurality of gate lines (scan signal lines) 109, a plurality of storage capacitor lines 111, and a plurality of source lines (display signal lines) 110 are placed.

The plurality of gate lines 109 and the plurality of storage capacitor lines 111 are arranged opposite to each other and in parallel with one another. Further, the plurality of source lines 110 are arranged in parallel with one another. The source lines 110 are arranged orthogonal to the gate lines 109 and the storage capacitor lines 111. A region surrounded by the adjacent gate line 109 and the storage capacitor line 111 and the two adjacent source lines 110 is the pixel 105. Thus, in the array substrate 100, the pixels 105 are arranged in matrix.

In the pixel 105, at least one pixel TFT 106 and at least one storage capacitor 108 are placed. The storage capacitor 108 is connected in series with the pixel TFT 106. The pixel TFT 106 serves as a switching element for supplying a display voltage to a pixel electrode. A gate electrode of the pixel TFT 106 is connected to the gate line 109, and on and off of the pixel TFT 106 are controlled according to a gate signal supplied from the gate line 109. A source electrode of the pixel TFT 106 is connected to the source line 110. When the pixel TFT 106 is turned on, a current flows from the source electrode side to the drain electrode side of the pixel TFT 106. A display voltage is thereby applied to the pixel electrode that is connected to the drain electrode. Then, an electric field corresponding to the display voltage is generated between the pixel electrode and a counter electrode. Further, the storage capacitor 108 is connected in parallel with the pixel electrode. Thus, at the same time as when a voltage is applied to the pixel electrode, a voltage is applied also to the storage capacitor 108, so that charges can be stored in the storage capacitor 108 for a given length of time.

Further, in the frame area 102 of the array substrate 100, a scan signal driver circuit 103 and a display signal driver circuit 104 are placed. The scan signal driver circuit 103 and the display signal driver circuit 104 include drive TFTs 107, which are formed simultaneously with the pixel TFTs 106 in the display area 101. The gate lines 109 extend from the display area 101 to the frame area 102. The gate lines 109 are connected to the scan signal driver circuit 103 in the frame area 102. Likewise, the source lines 110 extend from the display area 101 to the frame area 102, and are connected to the display signal driver circuit 104 in the frame area 102.

As other elements, external lines 112 connect from each of the scan signal driver circuit 103 and the display signal driver circuit 104 to external terminals disposed at the end of the array substrate 100. An IC chip 113 and a printed board 115 are mounted on and electrically connected to the external terminals. In this manner, various external signals are supplied to the scan signal driver circuit 103 and the display signal driver circuit 104 from the printed board 115 through the external terminals. Based on those signals, a gate signal (scan signal) is supplied to the gate line 109, and the TFTs 106 are selected sequentially. Likewise, a display signal is supplied to the source line 110, and a display voltage corresponding to display data is supplied to each pixel 105. Note that an alignment film is disposed on the top surface of the array substrate 100. The array substrate 100 is configured in the above manner.

A counter substrate, which is not shown, is placed opposite to the array substrate 100 configured as above. The counter substrate is a color filter substrate, for example, and placed on the viewing side. Although not illustrated, the counter substrate includes a color resist (color material), a black matrix (BM), a counter electrode, an alignment film and so on. Note that there is a case where the counter electrode is disposed on the array substrate 100 side, like an IPS (In-Plane Switching) liquid crystal display device, for example.

Liquid crystals are interposed between the array substrate 100 and the counter electrode. Further, a polarizing plate is attached to each of the outer sides of the array substrate 100 and the counter substrate. The liquid crystal display panel is configured in the above manner.

Further, on the non-viewing side of the liquid crystal display panel configured as above, a backlight unit is disposed with an optical film such as a phase difference plate interposed therebetween. Furthermore, the liquid crystal display panel and those peripheral parts are housed in a frame made of resin, metal or the like. The liquid crystal display device according to the first exemplary embodiment has the above-described structure.

Next, display operation of the liquid crystal display device according to the first exemplary embodiment is described briefly. The liquid crystals are driven by the electric field between the pixel electrode and the counter electrode. Specifically, the orientation of the liquid crystals between the substrates varies, and the amount of light passing through the liquid crystals varies accordingly. To be more precise, the amount of light passing through the polarizing plate on the viewing side, among transmitted light that is transmitted through the liquid crystal display panel from the backlight unit, varies. The orientation of the liquid crystals varies by the applied display voltage. Thus, the amount of light passing through the polarizing plate on the viewing side can be changed by controlling the display voltage. Specifically, the amount of light to be viewed as an image can be controlled. In the series of operation, the storage capacitor 108 contributes to maintaining the display voltage.

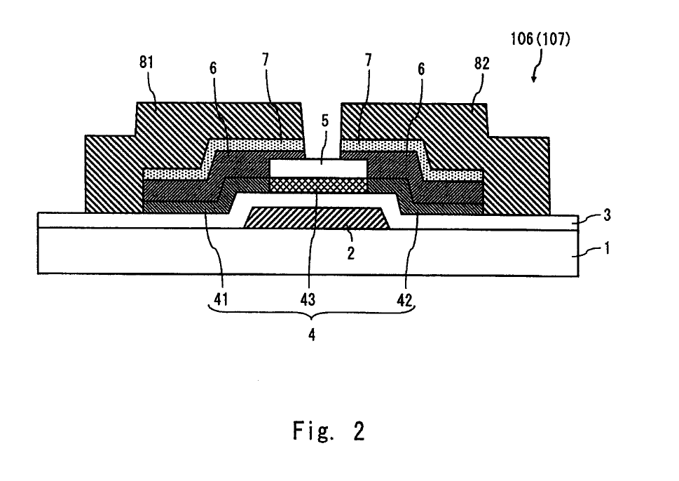

Hereinafter, a structure of a microcrystalline TFT which is used in the pixel TFT 106 and the drive TFT 107 disposed on the array substrate 100 is described in detail with reference to FIG. 2. FIG. 2 is a cross-sectional view showing the structure of the microcrystalline TFT according to the first exemplary embodiment. In the first exemplary embodiment, the pixel TFT 106 and the drive TFT 107 are formed simultaneously using the microcrystalline TFT having the same structure. Specifically, the pixel TFT 106 and the drive TFT 107 are identical. The microcrystalline TFT which is used in the liquid crystal display device according to the first exemplary embodiment is an inversely staggered TFT.

Referring to FIG. 2, on a transparent insulating substrate 1 such as glass or quartz, a gate electrode 2 is disposed in each of regions where the pixel TFT 106 and the drive TFT 107 are formed, respectively. The gate electrode 2 is made of aluminum (Al) or alloy containing Al, for example. The gate electrode 2 may be made of high melting point metal such as molybdenum (Mo) or chromium (Cr). Note that the end face of the gate electrode 2 is preferably in a forward tapered shape with respect to the substrate 1 as shown in FIG. 2. Specifically, the cross section of the gate electrode 2 preferably has a trapezoidal shape which narrows down from the bottom to the top. This improves the coating property of a layer disposed thereon and thereby improves the withstand voltage and reduces the occurrence of defect caused by break or the like.

Further, a gate insulating film 3 is disposed to cover the gate electrode 2. The gate insulating film 3 has a laminated structure in which an oxide film (SiO_{X} film) is laminated on a silicon nitride film (SiN film). Specifically, the laminated film in which the SiN film and the SiO_{X} film are laminated in this order from the substrate 1 side is formed as the gate insulating film 3. In this example, the gate insulating film 3 in which the SiO_{X} film with a thickness of about 60 nm is laminated on top of the SiN film with a thickness of about 300 nm is formed. Note that, although the gate insulating film 3 is not limited to the laminated film of the SiN film and the SiO_{X} film and may have another structure, a crystalline region 43 with good crystallinity can be obtained by a structure in which the oxide film is disposed at least in a part which comes into contact with a semiconductor film 4, which is described later.

The semiconductor film 4, which is an active layer, is disposed on the gate insulating film 3. The semiconductor film 4 is placed opposite to the gate electrode 2 with the gate insulating film 3 interposed therebetween. In this example, the semiconductor film 4 with a thickness of about 50 nm, for example, is formed. Further, the semiconductor film 4 is composed of a first amorphous region 41, a second amorphous region 42, and a crystalline region 43 placed between the first amorphous region 41 and the second amorphous region 42. The first amorphous region 41 and the second amorphous region 42 are amorphous semiconductor films such as amorphous silicon, for example. The amorphous region 41 acts as a source region, and the second amorphous region 42 acts as a drain region. The crystalline region 43 is a microcrystalline semiconductor film having microcrystals with a crystal grain diameter of 100 nm or less, such as microcrystalline silicon, and acts as a channel region.

In this manner, the first amorphous region 41 to serve as the source region and the second amorphous region 42 to serve as the drain region are placed at both ends of the semiconductor film 4. Further, the crystalline region 43 to serve as the channel region is placed between the source and drain regions of the semiconductor film 4.

On the semiconductor film 4, a translucent insulating film 5 is disposed. The translucent insulating film 5 is disposed on the crystalline region 43 of the semiconductor film 4. The translucent insulating film 5 is formed substantially all over the crystalline region 43 and not formed over the first amorphous region 41 and the second amorphous region 42. Thus, the translucent insulating film 5 is formed only on the crystalline region 43 of the semiconductor film 4. In other words, the crystalline region 43 of the semiconductor film 4 is formed only under the translucent insulating film 5. The translucent insulating film 5 is an insulating film having translucency such as a SiO_{X} film, and preferably a SiN film with a thickness of 20 to 40 nm. In this example, the translucent insulating film 5 is made of the SiN film with a thickness of 30 nm, for example.

On the translucent insulating film 5, an amorphous semiconductor layer 6 is disposed. Specifically, the amorphous semiconductor layer 6 is deposited in a region on the first amorphous region 41 and partly on the translucent insulating film 5 and in a region on the second amorphous region 42 and partly on the translucent insulating film 5, respectively.

The amorphous semiconductor layer 6 is disposed substantially all over the first amorphous region 41. The amorphous semiconductor layer 6 extends continuously from on the first amorphous region 41 to partly on the pattern of the translucent insulating film 5, lying over the pattern edge of the translucent insulating film 5. Likewise, the amorphous semiconductor layer 6 is disposed substantially all over the second amorphous region 42. The amorphous semiconductor layer 6 extends continuously from on the second amorphous region 42 to partly on the pattern of the translucent insulating film 5, lying over the pattern edge of the translucent insulating film 5. In this manner, on the semiconductor film 4, two patterns of the amorphous semiconductor layer 6 are provided. The two amorphous semiconductor layers 6 are separated on the translucent insulating film 5.

On the amorphous semiconductor layer 6, an ohmic contact layer 7 is disposed. The ohmic contact layer 7 is disposed substantially all over the amorphous semiconductor layer 6. The ohmic contact layer 7 is provided on each of the two amorphous semiconductor layers 6. The ohmic contact layer 7 is made of an amorphous semiconductor layer into which a conductive impurity is implanted and serves as a contact layer with a source electrode 81 and a drain electrode 82, which are described later.

On the ohmic contact layer 7, the source electrode 81 and the drain electrode 82 are placed. Specifically, the source electrode 81 is placed on the ohmic contact layer 7 on the first amorphous region 41 side of the semiconductor film 4. Further, the drain electrode 82 is placed on the ohmic contact layer 7 on the second amorphous region 42 side of the semiconductor film 4. The source electrode 81 and the drain electrode 82 are formed to extend to the outside of the semiconductor film 4. The source electrode 81 and the drain electrode 82 are formed to come into contact with the end face of the first amorphous region 41 or the second amorphous region 42. In this manner, the inversely staggered microcrystalline TFT is configured.

In the microcrystalline TFT configured as above, because the channel region of the semiconductor film 4 is formed by the microcrystalline semiconductor film (crystalline region 43), high mobility (3-4 cm²/Vs) and low threshold voltage shift can be achieved. Further, the microcrystalline semiconductor film (crystalline region 43) is formed only in the part of the semiconductor film 4 under the translucent insulating film 5, and the other part of the semiconductor film 4 is amorphous semiconductor films (the first amorphous region 41 and the second amorphous region 42). Therefore, direct contact of the source electrode 81 and the drain electrode 82 with the microcrystalline semiconductor can be avoided, so that the leakage current does not easily flow. Stated differently, in order that the leakage current during TFT-off does not easily flow to the source electrode 81 or the drain electrode 82, the structure avoids direct contact of the crystalline region 43 of the semiconductor film 4 with the source electrode 81 and the drain electrode 82. It is thereby possible to reduce the off-current. Accordingly, the microcrystalline TFT according to the first exemplary embodiment has favorable characteristics.

Note that, in the pixel TFT 106 and the drive TFT 107, a passivation film is formed to cover the whole TFT including the source electrode 81 and the drain electrode 82, although not shown in FIG. 2 because it is not a principal part of the present invention. Further, for the pixel TFT 106, the passivation film on the drain electrode 82 has an opening. Then, a pixel electrode which is connected to the drain electrode 82 through the opening is disposed on the passivation film. The pixel electrode is formed substantially all over the pixel 105.

The operation of the TFT which has the above structure and is used for the pixel TFT 106 and the drive TFT 107 is described briefly. When a gate voltage is applied to each gate electrode 2 of the pixel TFT 106 and the drive TFT 107, a channel is formed in the crystalline region 43, which is the channel region, of the semiconductor film 4 on the gate insulating film 3 side. Then, when a voltage is applied between the source electrode 81 and the drain electrode 82, a current flows between the first amorphous region 41, which is the source region, and the second amorphous region 42, which is the drain region.

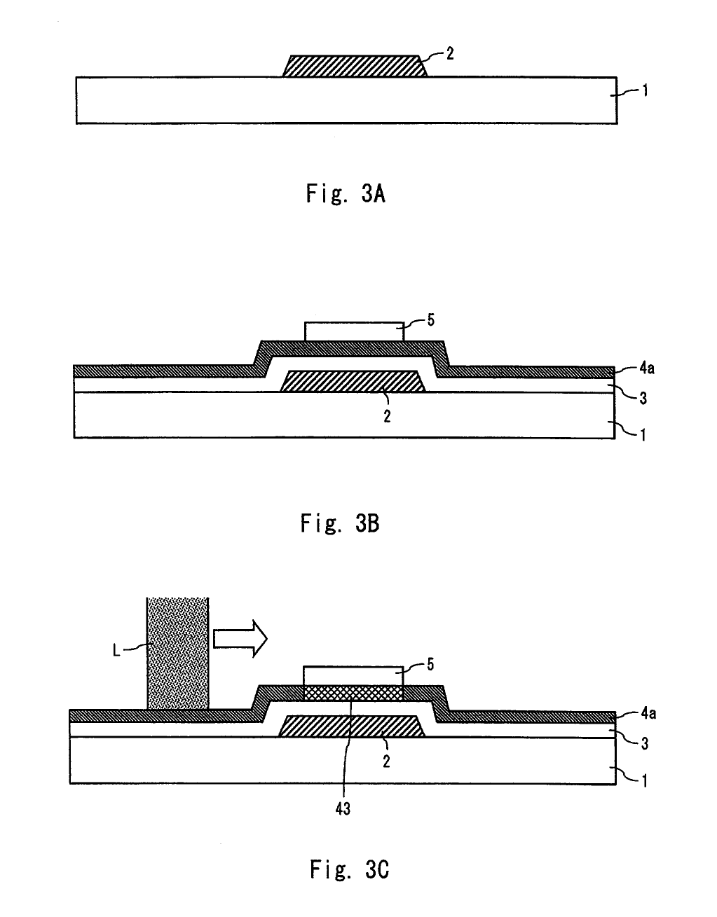

A manufacturing method of the liquid crystal display device according to the first exemplary embodiment is described hereinafter. First, a manufacturing method of the microcrystalline TFT, which is the principal part of the present invention, is described with reference to FIGS. 3A to 3E. FIGS. 3A to 3E are cross-sectional views showing a manufacturing process of the microcrystalline TFT according to the first exemplary embodiment. Each view of FIGS. 3A to 3E is a cross-sectional view of each manufacturing step in the part corresponding to FIG. 2.

First, a metal film to serve as the gate electrode 2 is deposited on the substrate 1 using sputtering. As the substrate 1, a transparent insulating substrate such as a glass substrate may be used. As the metal film to serve as the gate electrode 2, aluminum (Al) or alloy containing Al may be used. Preferably, molybdenum (Mo), chromium (Cr) or the like, which is high melting point metal, is used as the metal film to serve as the gate electrode 2. By using the high melting point metal as the metal film to serve as the gate electrode 2, thermal damage in excimer laser irradiation, which is described later, can be reduced.

On the deposited metal film, photoresist, which is photosensitive resin, is coated by spin coating. Then, the first photolithography process that performs exposure and development of the coated photoresist is conducted. The photoresist is thereby patterned into a desired shape, and a resist pattern is formed on the metal film. Using the resist pattern as a mask, the metal film is etched and patterned into a desired shape. After that, the resist pattern is removed. The gate electrode 2 in a given pattern shape is thereby formed as shown in FIG. 3A. Note that it is preferred to form the gate electrode 2 so that the end face of the gate electrode 2 has a tapered shape. The tapered shape improves the coating property of a film deposited subsequently. For example, when the film deposited subsequently is the gate insulating film 3, the effect of improving a withstand voltage is exerted.

Next, the gate insulating film 3, an amorphous semiconductor film 4a, and the translucent insulating film 5 are deposited. Specifically, the gate insulating film 3 is formed to cover the gate electrode 2. Then, on the gate insulating film 3, the amorphous semiconductor film 4a, which is a first semiconductor film, and the translucent insulating film 5 are stacked in this order. The gate insulating film 3, the amorphous semiconductor film 4a, and the translucent insulating film 5 are deposited in succession all over the substrate 1 by using plasma CVD, for example.

For example, as the gate insulating film 3, a laminated film in which a silicon nitride film (SiN film) and an oxide film (SiO_{X} film) are laminated in this order from the substrate 1 side is formed. Note that, although an insulating film of a different structure may be used as the gate insulating film 3, by forming an insulating film that has the SiO_{X} film at least in a part coming into contact with the amorphous semiconductor film 4a as described above, the crystallinity of the crystalline region 43 which is formed by excimer laser irradiation, which is described later, is improved. Particularly, the crystallinity in the vicinity of the interface of the side of the gate insulating film 3 with the SiO_{X} film in the crystalline region 43 can be maintained.

Further, as the amorphous semiconductor film 4a, an amorphous silicon film is formed, for example. As the material of the translucent insulating film 5, although an insulating film having translucency such as a SiO_{X} film, for example, may be used, it is preferred to use a SiN film. This is because, at the time of excimer laser irradiation in the subsequent step, the SiN film effectively functions as anti-reflection coating that reduces laser light reflected on the surface of the amorphous semiconductor film 4a and allows the laser light to be efficiently absorbed into the amorphous semiconductor film 4a under the translucent insulating film 5.

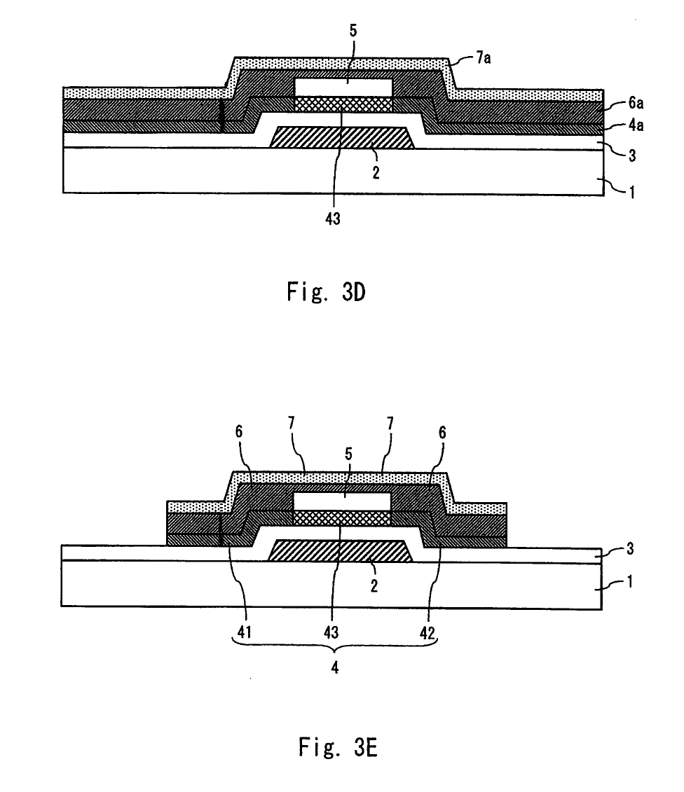

A relationship between the thickness of the SiN film formed as the translucent insulating film 5 on the amorphous semiconductor film 4a and the reflectance of laser light applied through the SiN film on the surface of the amorphous semiconductor film 4a is described with reference to FIG. 4. FIG. 4 is a graph showing the relationship between the reflectance of laser light on the surface of the amorphous silicon film and the thickness of the SiN film. FIG. 4 shows a change in the reflectance of laser light on the surface of the amorphous semiconductor film 4a with respect to a change in the thickness of the SiN film formed thereon, where an amorphous silicon film is used as the amorphous semiconductor film 4a.

The graph of FIG. 4 shows that the reflectance of laser light on the surface of the amorphous silicon film changes depending on the thickness of the SiN film formed thereon. Specifically, compared to the case where there is no SiN film (when the thickness of the SiN film is 0 in FIG. 4), the reflectance on the surface of the amorphous silicon film (Si surface reflectance) decreases periodically in the relationship as represented by the following expression (1):

Si surface reflectance=(2m−1)λ/(4·n) Expression (1)

where m is an integer, λ is a laser light wavelength (308 nm), and n is a refractive index of SiN film.

As the reflectance on the surface of the amorphous silicon film decreases, absorption of laser light into the amorphous silicon film increases accordingly.

Although the periodic reflectance characteristics are exhibited with respect to the thickness of the SiN film, etching time can be shorter with a relatively thin film, which is suitable in terms of productivity. Thus, when using the SiN film as the translucent insulating film 5, the thickness is preferably in the range of 20 to 40 nm. More preferably, the SiN film with a thickness of 30 nm is deposited as the translucent insulating film 5. The reflectance of laser light on the surface of the amorphous silicon film is about 11% when applying laser light to the amorphous silicon film through the SiN film with a thickness of 30 nm, and about 56% when applying laser light to the amorphous silicon film directly without through the SiN film, and there is a difference of about 45% between them.

After that, on the deposited translucent insulating film 5, a resist pattern of a given shape is formed by the second photolithography process. Using the resist pattern as a mask, the translucent insulating film 5 is etched and patterned. Consequently, the translucent insulating film 5 having the given shape is formed on a formation area of the channel region of the amorphous semiconductor film 4a as shown in FIG. 3B. In an area different from the formation area of the channel region, the surface of the amorphous semiconductor film 4a is exposed.

The amorphous semiconductor film 4a with the exposed surface is likely to form a natural oxide film. Thus, the natural oxide film on the surface of the amorphous semiconductor film 4a is removed by using hydrofluoric acid such as dilute hydrofluoric acid or buffered hydrofluoric acid with a concentration of several %.

By removing the natural oxide film, a contamination from the atmosphere can be removed at the same time. Further, a residue of the etching of the translucent insulating film 5 may be removed at the same time as removing the natural oxide film. However, because the hydrofluoric acid slightly etches the translucent insulating film 5 also at the same time, it is preferred to make adjustment in advance so that the thicknesses of the amorphous semiconductor film 4a and the translucent insulating film 5 after removal of the natural oxide film are as designed.

Then, laser annealing that irradiates the amorphous semiconductor film 4a above the substrate 1 with laser light such as excimer laser is performed immediately after the removal of the natural oxide film. In the laser annealing, laser irradiation is applied, scanning the entire substrate 1 with laser light L in a wide line beam as shown in FIG. 3C. In this step, in the amorphous semiconductor film 4a, a region covered with the translucent insulating film 5 is irradiated with the laser light L through the translucent insulating film 5, and a region not covered with the translucent insulating film 5 is irradiated with the laser light L directly without through the translucent insulating film 5. In the region irradiated with the laser light L through the translucent insulating film 5, the reflectance of the laser light L on the surface of the amorphous semiconductor film 4a is reduced by the translucent insulating film 5, and therefore the laser light L can be efficiently absorbed into the amorphous semiconductor film 4a.

The irradiation conditions of the laser light L are that the part of the amorphous semiconductor film 4a under the translucent insulating film 5 is converted into a microcrystalline semiconductor film having microcrystals with a crystal grain diameter of 100 nm or less and that the part of the amorphous semiconductor film 4a other than under the translucent insulating film 5 maintains the amorphous state. Specifically, the irradiation energy density of the laser light L is set to be higher than the condition in which the part of the amorphous semiconductor film 4a under the translucent insulating film 5 is converted into a microcrystalline semiconductor film having microcrystals with a crystal grain diameter of 100 nm or less by the laser light L which is absorbed into the amorphous semiconductor film 4a through the translucent insulating film 5. Further, the irradiation energy density of the laser light L is set to the condition in which the part of the amorphous semiconductor film 4a on which the translucent insulating film 5 is not disposed maintains the amorphous state by the laser light L which is irradiated directly without through the translucent insulating film 5 and absorbed (the condition lower than the condition for crystallization).

Thus, when the laser light L is irradiated under such conditions, the part of the amorphous semiconductor film 4a under the translucent insulating film 5 is crystallized into the microcrystalline semiconductor film. Specifically, the laser light L which is absorbed into the amorphous semiconductor film 4a is converted into heat, and the amorphous semiconductor film 4a is melt by the heat, and then the amorphous semiconductor film 4a under the translucent insulating film 5 is converted into the microcrystalline semiconductor film having microcrystals with a crystal grain diameter of 100 nm or less. On the other hand, the part of the amorphous semiconductor film 4a other than under the translucent insulating film 5 is not crystallized and remains in the amorphous state.

As described above, only a part of the amorphous semiconductor film 4a is crystallized by use of a difference in the reflectance of the laser light L on the surface of the amorphous semiconductor film 4a which is caused by the translucent insulating film 5 placed partially. Consequently, as shown in FIG. 3C, a part of the amorphous semiconductor film 4a is converted into the microcrystalline semiconductor film, thus becoming the crystalline region 43. Note that, if an oxide film is disposed in the part of the gate insulating film 3 which comes into contact with the crystalline region 43 crystallized in this step, the crystalline region 43 is formed directly on the oxide film, so that the crystalline region 43 with good crystallinity can be obtained.

Detailed explanation about the conversion from the amorphous semiconductor film 4a into the microcrystalline semiconductor film by the laser light L is added below. First, the thicknesses of the SiN film and the SiO_{X} film which are deposited as the gate insulating film 3 in the step of forming the gate insulating film 3 described above are about 300 nm and about 60 nm, respectively, for example. When the SiO_{X} film is formed thick in this way, the laser light L which is absorbed into the amorphous semiconductor film 4a is converted into heat, and the heat is accumulated in the SiO_{X} film. Thus, the SiO_{X} film serves as a buffer film, and the irradiation energy density of the laser light L necessary for converting into the microcrystalline semiconductor film can be suppressed.

Further, the thickness of the amorphous semiconductor film 4a which is deposited in the step of depositing the amorphous semiconductor film 4a described above is about 50 nm, for example. Although use of the thinner amorphous semiconductor film 4a enables reduction of the irradiation energy density of the laser light L, it is preferred to determine the deposition thickness in consideration of that the amorphous semiconductor film 4a may be cut away by the etching of the translucent insulating film 5 described above when using the thinner film. Further, when the amorphous semiconductor film 4a is as thin as about 10 nm, for example, the agglomeration of silicon occurs at the time of heat melting by the laser annealing, which is not preferable. Further, for the purpose of suppressing ablation or the like of the amorphous semiconductor film 4a by the excimer laser exposure, dehydrogenation that performs heat treatment at 300° C. or higher, or at 400° C. preferably, is carried out before the excimer laser irradiation.

A specific appropriate range of the irradiation energy density of the laser light L is 100 to 130 mJ/cm². This is for the following reason.

When the amorphous semiconductor film 4a is irradiated with the laser light L through the translucent insulating film 5 made of the SiN film with a thickness of 30 nm, melting starts from the surface of the amorphous semiconductor film 4a with the irradiation energy density of 80 mJ/cm² or higher, and conversion is made into the microcrystalline semiconductor film with 100 to 130 mJ/cm². Therefore, the irradiation energy density necessary for completely melting the part of the amorphous semiconductor film 4a under the translucent insulating film 5 and then converting it into the microcrystalline semiconductor film having microcrystals with a crystal grain diameter of 100 nm or less is preferably in the range of 100 to 130 mJ/cm².

On the other hand, when the amorphous semiconductor film 4a is irradiated with the laser light L directly without through the translucent insulating film 5, the reflectance of the laser light L on the surface of the amorphous semiconductor film 4a is higher than when irradiated through the translucent insulating film 5, and the absorption into the amorphous semiconductor film 4a is reduced. Therefore, the irradiation energy density necessary for melting the surface of the amorphous semiconductor film 4a directly irradiated with the laser light L is 140 mJ/cm². Therefore, with the irradiation energy density in the range of 100 to 130 mJ/cm² described above, it does not reach the temperature high enough to melt the amorphous semiconductor film 4a directly irradiated with the laser light L, and the state of the amorphous semiconductor film 4a is maintained.

As described above, when the irradiation energy density of the laser light L is in the range of 100 to 130 mJ/cm², only the part of the amorphous semiconductor film 4a under the translucent insulating film 5 can be converted into the microcrystalline semiconductor film to form the crystalline region 43 having microcrystals, while the other part of the amorphous semiconductor film 4a remains in the amorphous state.

Note that, if the irradiation energy density of the laser light L is set higher than the above range, the crystal grain diameter obtained by crystallization becomes larger, and a polycrystalline semiconductor film can be formed. However, because the crystalline region 43 desirable in the present invention is a microcrystalline semiconductor film, it is not necessary to increase the irradiation energy density of the laser light L any more. Further, an increase in the irradiation energy density of the laser light L causes crystallization of the amorphous semiconductor film 4a in the formation area of the first amorphous region 41 and the second amorphous region 42 as well, which is not preferable.

As described above, the crystallization method of the amorphous semiconductor film according to the first exemplary embodiment is a laser crystallization method that uses a difference in reflectance between the amorphous semiconductor film 4a irradiated with the laser light L through the translucent insulating film 5 as anti-reflection coating and the amorphous semiconductor film 4a irradiated with the laser light L directly. In this crystallization method, the semiconductor film having two different regions of the amorphous region and the crystalline region can be obtained.

Note that the detailed explanation about the conversion from the amorphous semiconductor film 4a into the microcrystalline semiconductor film by the laser light L described above is just an example, and the present invention is not limited thereto. For example, the translucent insulating film 5 is not limited to the SiN film, and the thickness may be varied as appropriate. Further, the appropriate range of the irradiation energy density of the laser light L may be adjusted appropriately depending on the condition at the time of irradiation or the like.

After the laser annealing is performed in the above manner, an amorphous semiconductor film 6a and an amorphous semiconductor film 7a containing an impurity are formed in this order on the translucent insulating film 5. For example, an amorphous silicon film is formed as the amorphous semiconductor film 6a, which is a second semiconductor film. Further, an amorphous silicon film containing an n-type impurity is formed as the amorphous semiconductor film 7a containing an impurity, which is a third semiconductor film. The amorphous semiconductor film 6a and the amorphous semiconductor film 7a containing an impurity can be formed continuously in the same device or the same chamber. Alternatively, after depositing the amorphous semiconductor film 6a, an impurity may be implanted into a part of the deposited amorphous semiconductor film 6a to thereby form an impurity region on the surface of the amorphous semiconductor film 6a, which serves as the amorphous semiconductor film 7a containing an impurity. The structure shown in FIG. 3D is thereby produced.

Then, the third semiconductor film, the second semiconductor film and the first semiconductor layer are patterned. Specifically, a laminated film composed of the amorphous semiconductor film 7a containing an impurity, the amorphous semiconductor film 6a, and the amorphous semiconductor film 4a is patterned by the third photolithography process and the etching process. Specifically, the amorphous semiconductor film 7a containing an impurity, the amorphous semiconductor film 6a, and the amorphous semiconductor film 4a are patterned sequentially in one photolithography process.

In this manner, the laminated film composed of the amorphous semiconductor film 7a containing an impurity, the amorphous semiconductor film 6a, and the amorphous semiconductor film 4a is patterned into an island shape which is separated to respective TFTs. In the first exemplary embodiment, the first semiconductor film is patterned into a shape which includes the crystalline region 43 crystallized in the laser annealing, and the first amorphous region 41 and the second amorphous region 42 made of the amorphous semiconductor films 4a placed opposite to each other with the crystalline region 43 interposed therebetween. The structure shown in FIG. 3E is thereby produced.

Next, a metal film to serve as the source electrode 81 and the drain electrode 82 is deposited to cover the laminated film composed of the amorphous semiconductor film 7a containing an impurity, the amorphous semiconductor film 6a, and the amorphous semiconductor film 4a. The metal film is deposited all over the substrate 1 by sputtering, for example. Then, the metal film is patterned into a desired shape by the fourth photolithography process and etching. The source electrode 81 and the drain electrode 82 are thereby formed.

Then, by using the source electrode 81 and the drain electrode 82 as a mask and the translucent insulating film 5 as an etching stopper, the amorphous semiconductor film 7a containing an impurity and the amorphous semiconductor film 6a on the translucent insulating film 5 are etched away. For example, the amorphous semiconductor film 7a containing an impurity and the amorphous semiconductor film 6a are removed until reaching the translucent insulating film 5 between the source electrode 81 and the drain electrode 82 by dry etching. Consequently, as shown in FIG. 2, the amorphous semiconductor film 7a containing an impurity is separated above the translucent insulating film 5, and two ohmic contact layers 7 separated from each other are formed. Likewise, the amorphous semiconductor film 6a is separated on the translucent insulating film 5, and two amorphous semiconductor layers 6 separated from each other are formed. The amorphous semiconductor layers 6 extends from on the first amorphous region 41 and the second amorphous region 42 of the semiconductor film 4 to partly on the translucent insulating film 5.

In this manner, the TFT according to the first exemplary embodiment is completed. Specifically, the inversely staggered TFT having the active layer, which is the semiconductor film 4 composed of two different regions of the first amorphous region 41 and the second amorphous region 42, and the crystalline region 43, is formed as the pixel TFT 106 and the drive TFT 107 shown in FIG. 1. The TFT is formed as the pixel TFT 106 in the display area 101, and formed as the drive TFT 107 in the scan signal driver circuit 103 and the display signal driver circuit 104.

Besides, for completion of the array substrate 100, after forming the source electrode 81 and the drain electrode 82, the passivation film is formed to cover them entirely, although not shown in FIG. 2. Further, for the pixel TFT 106, an opening is formed in a part of the passivation film on the drain electrode 82 by the fifth photolithography process and etching. Then, a pixel electrode is formed on the passivation film by the sixth photolithography process and etching. Further, by the first to sixth photolithography processes and the etching described above, the elements other than the pixel TFT 106 and the drive TFT 107, such as the gate lines 109, the storage capacitor lines 111, the source lines 110, the storage capacitors 108, the external terminals and so on, are formed simultaneously. In the above manner, the array substrate 100 described with reference to FIG. 1 is completed.

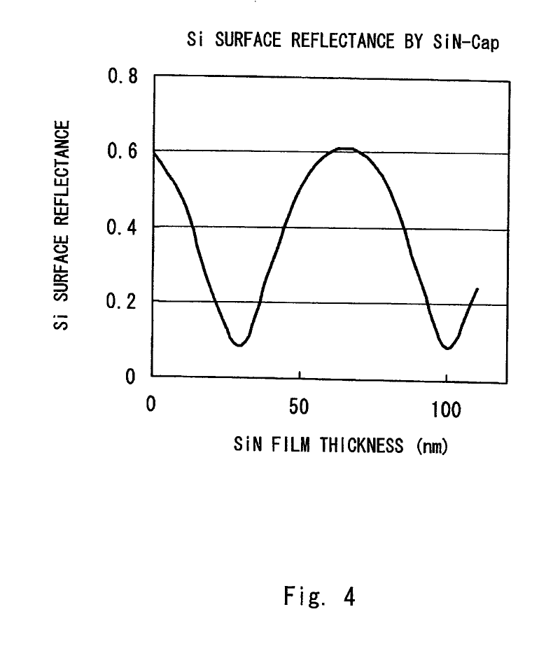

Hereinafter, a cell assembly process when manufacturing the liquid crystal display device using the array substrate 100 fabricated as above is described hereinafter with reference to FIG. 5. FIG. 5 is a schematic plan view showing a structure of a mother liquid crystal cell substrate in the manufacturing process of the liquid crystal display device according to the first exemplary embodiment.

In the case of manufacturing a small liquid crystal display device, a mother liquid crystal cell substrate 10 in which a plurality of liquid crystal cell substrates 10a, 10b, . . . 10n are arranged in an array in a segmented manner as shown in FIG. 5 is generally formed in terms of mass production efficiency. Specifically, the mother liquid crystal cell substrate 10 is in the state where the liquid crystal cell substrates 10a, 10b, . . . 10n are arranged in an array in a multifaceted manner. The liquid crystal cell substrates 10a, 10b, . . . 10n are cut out of the mother liquid crystal cell substrate 10 into a size of each liquid crystal display panel, so that the liquid crystal display panel as shown in FIG. 1 is obtained. Thus, in the manufacturing method of the array substrate 100 described above, by producing a single mother array substrate 1a, which is a large substrate in which a plurality of array substrates 100 are arranged in an array in a segmented manner, the plurality of array substrates 100 can be manufactured simultaneously.

Specifically, the mother array substrate 1a manufactured by the manufacturing method of the array substrate 100 described above is prepared, and a mother counter substrate (not shown) which is placed opposite to the mother array substrate 1a is prepared. The mother counter substrate may be a general substrate including a color filter (color material), a black matrix (BM), a counter electrode so on. An alignment film is formed on each of the surfaces of the mother array substrate 1a and the mother counter substrate by a general method. After that, a sealing pattern that surrounds a liquid crystal sealing area is formed corresponding to each of the liquid crystal cell substrates 10a, 10b, . . . 10n in one substrate, and the mother array substrate 1a and the mother counter substrate are bonded together. The mother liquid crystal cell substrate 10 shown in FIG. 5 is thereby produced.

Note that the liquid crystals may be injected into the sealing pattern by vacuum injection which is performed in vacuum through an injection port after bonding or by liquid crystal dropping which drops liquid crystals in the sealing pattern and simultaneously performs liquid crystal injection and bonding. The liquid crystal cell substrate cutout process that cuts out the substrate into a size of each liquid crystal display panel is performed before the liquid crystal injection in the case of the vacuum injection, and performed after the liquid crystal injection in the case of the liquid crystal dropping. In this manner, the cell assembly process is completed, and the liquid crystal cell substrates 10a, 10b, . . . 10n are obtained.

Finally, the polarizing plate is attached to each of the outer sides of the array substrates 100 and the counter substrate of the liquid crystal cell substrates 10a, 10b, . . . , 10n. Further, the IC chip 113 and the printed board 115 are mounted on the external terminals formed on the array substrate 100. In order to perform the mounting smoothly, the counter substrate is cut in advance so that the external terminals formed on the array substrate 100 projects from the counter substrate, which is, the counter substrate is not placed opposite to the external terminals. In the above manner, the liquid crystal display panel shown in FIG. 1 is completed.

Further, on the backside of the array substrates 100, which is the non-viewing side of the liquid crystal display panel, the backlight unit is disposed with an optical film such as a phase difference plate interposed therebetween. Furthermore, the liquid crystal display panel and those peripheral parts are housed as appropriate in a frame made of resin, metal or the like. The liquid crystal display device according to the first exemplary embodiment is thereby completed.

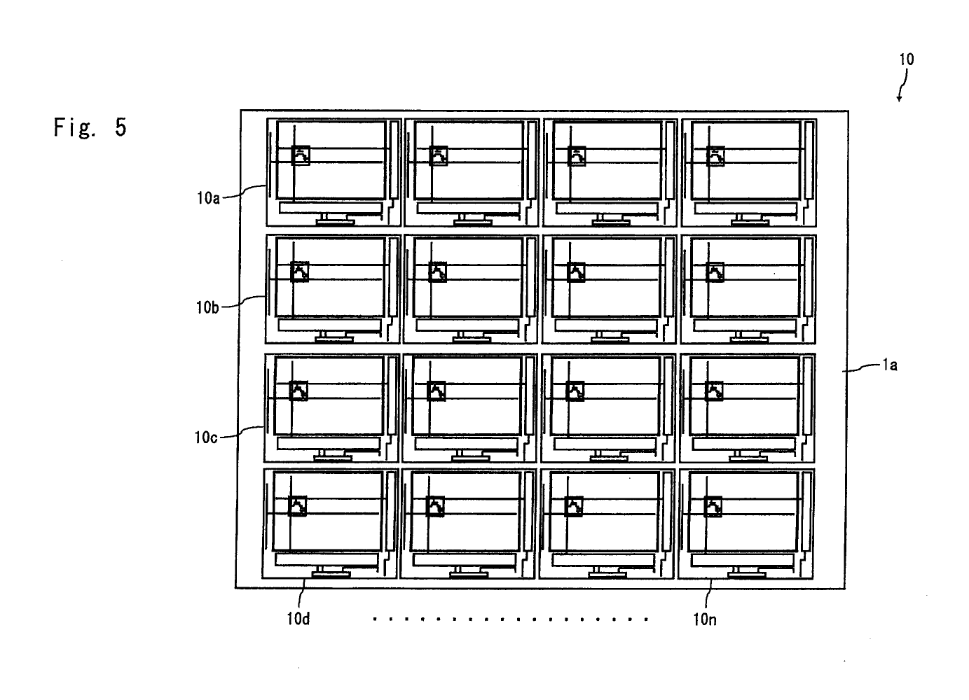

Hereinafter, the function of the liquid crystal display device using the microcrystalline TFT according to the first exemplary embodiment is described in comparison with a liquid crystal display device used heretofore. FIG. 6 is a plan view showing a liquid crystal display panel of a liquid crystal display device using a typical amorphous TFT used heretofore.

In the amorphous TFT, threshold voltage shift occurs generally when operating continuously for a long time, and ceases to perform normal drive operation. However, in the drive TFT 107 that constitutes the driver circuit shown in FIG. 1, some TFT operates constantly. Thus, if the amorphous TFT is used as the drive TFT 107 which needs to operate constantly in the driver circuit in the liquid crystal display device, the threshold voltage shift occurs and normal drive operation is failed. As a result, normal display is failed. Further, in order to perform a desired driver circuit operation as the drive TFT 107 in the driver circuit, a certain degree of TFT driving capability is required. Although it can be satisfied technically with use of the amorphous TFT by increasing the TFT size, the area of the driver circuit becomes enormous.

Thus, although it is possible to use the amorphous TFT as the pixel TFT 106 for switching, the amorphous TFT is usually not selected as a TFT to be used as the driver circuit which is disposed on the substrate such as the scan signal driver circuit 103 and the display signal driver circuit 104 shown in FIG. 1. Therefore, in a typical liquid crystal display device used heretofore, which uses the amorphous TFT, it is necessary to add several external IC chips 114 for operation of the driver circuit instead of the scan signal driver circuit 103 and the display signal driver circuit 104 as shown in FIG. 6. As a result, the number of IC chips 113 and 114 increases as a whole.

On the other hand, in the liquid crystal display device according to the first exemplary embodiment, the microcrystalline TFTs having the above-described structure can be formed simultaneously for the pixel TFT 106 and the drive TFT 107. Further, after the amorphous semiconductor film 4a is deposited, the translucent insulating film 5 is formed thereon only for the drive TFT 107, so that the microcrystalline TFT can be formed only in the drive TFT 107, and the amorphous TFT can be formed in the pixel TFT 106 at the same time. Specifically, it is possible to provide the suitable amorphous TFT in the pixel TFT 106 formed in the pixel 105 and provide the microcrystalline TFT with less threshold voltage shift in the drive TFT 107 for the scan signal driver circuit 103 and the display signal driver circuit 104.

In any case, by forming the microcrystalline TFT as the drive TFT 107, the number of parts of the IC chips 114 at least can be reduced, and a relatively large placement space for the IC chips 113 and 114 can be eliminated. This enables reduction of the number of parts, weight saving of the liquid crystal display device, and narrower frame of the liquid crystal display device (size reduction per display area required). Further, because the mounting process of the IC chips 114 can be eliminated, the manufacturing productivity can be improved, including preventing the occurrence of a quality loss due to defective. Further, in the case of forming the amorphous TFT as the pixel TFT 106 and forming the microcrystalline TFT as the drive TFT 107, the amorphous TFT and the microcrystalline TFT can be formed simultaneously in the manufacturing process, and the productivity does not decrease. As a result, the productivity in the entire manufacture is improved, and cost reduction can be achieved.

As described above, according to the first exemplary embodiment, manufacturing facilities (manufacturing devices) generally installed in liquid crystal display panel makers may be used without the need for any special technique or management. The use of the microcrystalline TFT enables the following advantageous effects to be achieved at the same time. One effect is to suppress the display unevenness by easily reducing variation of TFT characteristics of the pixel TFT 106 and leakage current. Another effect is to enable the reduction of the number of parts, the weight saving of the liquid crystal display device, the narrower frame of the liquid crystal display device, and the improvement of productivity in manufacture by replacing some of the IC chips with the driver circuits formed on the substrate. Yet another effect is to narrow the frame of the liquid crystal display device by placing the scan signal driver circuit 103 and the display signal driver circuit 104 in close proximity to the display area 101.

As described above, according to the first exemplary embodiment, the laser light L is irradiated by utilization of the translucent insulating film 5 of a given shape which is formed on the amorphous semiconductor film 4a, thereby forming the semiconductor film 4 in which the crystalline region 43 is placed between the first amorphous region 41 and the second amorphous region 42. The microcrystalline TFT can be thereby formed with high mobility and low threshold voltage shift that satisfy the requirement for the drive TFT 107. Further, because the crystalline region 43 can be formed only under the translucent insulating film 5, the source electrode 81 and the drain electrode 82 do not come into direct contact with the crystalline region 43. The microcrystalline TFT can be thereby formed with low off-current that satisfies the requirement for the pixel TFT 106. Accordingly, the TFT with favorable characteristics which are compatible with both the pixel TFT 106 and the drive TFT 107, can be formed relatively easily. Therefore, it is possible to provide a crystallization method of an amorphous semiconductor film which can easily obtain a semiconductor film with favorable characteristics, and a thin film transistor, a semiconductor device, and a manufacturing method of a thin film transistor which apply the same.

Note that, although the case where the microcrystalline TFT according to the present invention is applied to the pixel TFT 106 and the drive TFT 107 constituting the scan signal driver circuit 103 or the display signal driver circuit 104 in a typical liquid crystal display device is described by way of illustration in the first exemplary embodiment, the scope of application of the present invention is not limited thereto. For example, in a liquid crystal display device with a built-in optical sensor, a drive TFT for driving an element in the optical sensor or the like is used in addition to the drive TFT for a display signal. The microcrystalline TFT according to the present invention may be applied also to such a drive TFT.

Note that, in the crystallization process of the amorphous semiconductor film 4a, for example, crystal grains may be formed larger by controlling irradiation conditions such as the irradiation energy of the laser light L, the atmosphere during irradiation and the substrate temperature in the first exemplary embodiment. Specifically, the semiconductor layer crystallized in the crystallization process is not limited to microcrystalline silicon, and it may be polycrystalline silicon. The same advantageous effects as in the first exemplary embodiment can be obtained as long as it is a crystalline semiconductor film. However, the use of the microcrystalline semiconductor film is preferred because the range of applied conditions is wider and the manufacture is easier, and variation of characteristics of the TFT using the obtained crystalline semiconductor film can be reduced. Although the silicon is described as an example of the semiconductor, other semiconductors may be used as long as it can be converted from an amorphous semiconductor into a microcrystalline or crystalline semiconductor by laser irradiation.

Further, the application of the microcrystalline TFT described in the first exemplary embodiment is not limited to the liquid crystal display device, and semiconductor devices such as an organic EL display device, other display devices and imaging devices may be used. Thus, the microcrystalline TFT described in the first exemplary embodiment is applicable to driver circuits that drive various elements as long as it is a TFT constituting the driver circuit. For example, it is applicable also to a TFT which is used in a logic circuit that performs digital operation. When applied to any circuits, the same advantageous effects as in the first exemplary embodiment can be obtained, such as achieving high speed operation without increasing the circuit area, eliminating the need for new IC chips, and preventing an increase in size and cost of a display device or a semiconductor device.

### Second Exemplary Embodiment

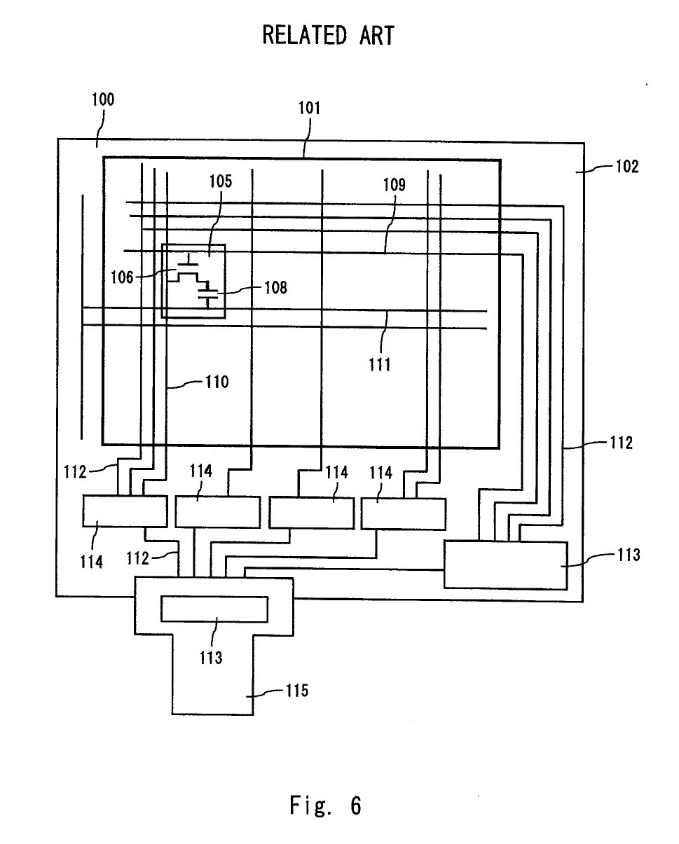

A structure of a microcrystalline TFT according to a second exemplary embodiment is described hereinafter with reference to FIG. 7. FIG. 7 is a cross-sectional view showing the structure of the microcrystalline TFT according to the second exemplary embodiment. In the second exemplary embodiment, the structure of the microcrystalline TFT is different from that of the first exemplary embodiment, and the other elements are the same as those of the first exemplary embodiment and thus not redundantly described. Hereinafter, the microcrystalline TFT according to the second exemplary embodiment, which is an alternative example of the microcrystalline TFT according to the first exemplary embodiment, is described.

In FIG. 7, the gate electrode 2 is disposed on the substrate 1, and the gate insulating film 3 is disposed to cover the gate electrode 2, as in the first exemplary embodiment. The semiconductor film 4 is disposed on the gate insulating film 3. The semiconductor film 4 has a different structure from the first exemplary embodiment. Specifically, in the second exemplary embodiment, the semiconductor film 4 is composed of a first amorphous region 41a containing an impurity, a second amorphous region 42a containing an impurity, and a crystalline region 43 placed between the first amorphous region 41a and the second amorphous region 42a. The first amorphous region 41a and the second amorphous region 42a into which a conductive impurity is implanted function as a contact layer with the source electrode 81 and the drain electrode 82.

Further, the translucent insulating film 5 is disposed on the crystalline region 43 of the semiconductor film 4, as in the first exemplary embodiment. In the second exemplary embodiment, the source electrode 81 and the drain electrode 82 are disposed on the translucent insulating film 5. Specifically, the source electrode 81 and the drain electrode 82 are disposed in a region from on the first amorphous region 41a to partly on the translucent insulating film 5 and in a region from on the second amorphous region 42a to partly on the translucent insulating film 5, respectively. In this manner, the source electrode 81 is formed on the first amorphous region 41a in direct contact, and the drain electrode 82 is formed on the second amorphous region 42a in direct contact. Further, the source electrode 81 and the drain electrode 82 are formed to come into contact with the end face of the first amorphous region 41a or the second amorphous region 42a.

To fabricate the microcrystalline TFT in such a structure, after forming the translucent insulating film 5 and before performing laser annealing, an impurity is implanted into the amorphous semiconductor film 4a by using the translucent insulating film 5 as a mask. Specifically, impurity implantation is conducted in the state shown in FIG. 3B of the first exemplary embodiment. Note that, although the case where impurity implantation is performed using the translucent insulating film 5 as a mask is described by way of illustration, impurity implantation may be performed using both of the translucent insulating film 5 and a resist pattern formed thereon as a mask. Specifically, after patterning the translucent insulating film 5, impurity implantation may be performed in the state before removing the resist pattern used for patterning the translucent insulating film 5.

After that, by laser annealing, the amorphous semiconductor film 4a under the translucent insulating film 5 is crystallized, and the impurity-implanted portion of the amorphous semiconductor film 4a is activated by addition of heating (annealing) treatment.

Next, the amorphous semiconductor film 4a is patterned into a given shape which includes the crystalline region 43 crystallized by laser annealing and the first amorphous region 41a and the second amorphous region 42a made of the amorphous semiconductor film 4a placed opposite to each other with the crystalline region 43 placed therebetween. The semiconductor film 4 is thereby formed. Then, on the semiconductor film 4, a metal film to serve as the source electrode 81 and the drain electrode 82 is deposited, and the deposited metal film is patterned to form the source electrode 81 and the drain electrode 82.

As described above, according to the second exemplary embodiment, the step of implanting an impurity into a region different from the region where the translucent insulating film 5 is formed is added, so that the first amorphous region 41a and the second amorphous region 42a of the semiconductor film 4 can function as a contact layer. This eliminates the need to form the amorphous semiconductor layer 6 on the semiconductor film 4, thereby reducing the defect level which hinders the on-current from flowing at the interface of the first amorphous region 41 and the second amorphous region 42 with the amorphous semiconductor layer 6 in the microcrystalline TFT according to the first exemplary embodiment. Therefore, more favorable TFT characteristics can be obtained. Further, direct contact of the source electrode 81 and the drain electrode 82 with the crystalline region 43 is avoided, and the same advantageous effects as the first exemplary embodiment, which is reduction of the off-current, can be exerted.

### Third Exemplary Embodiment

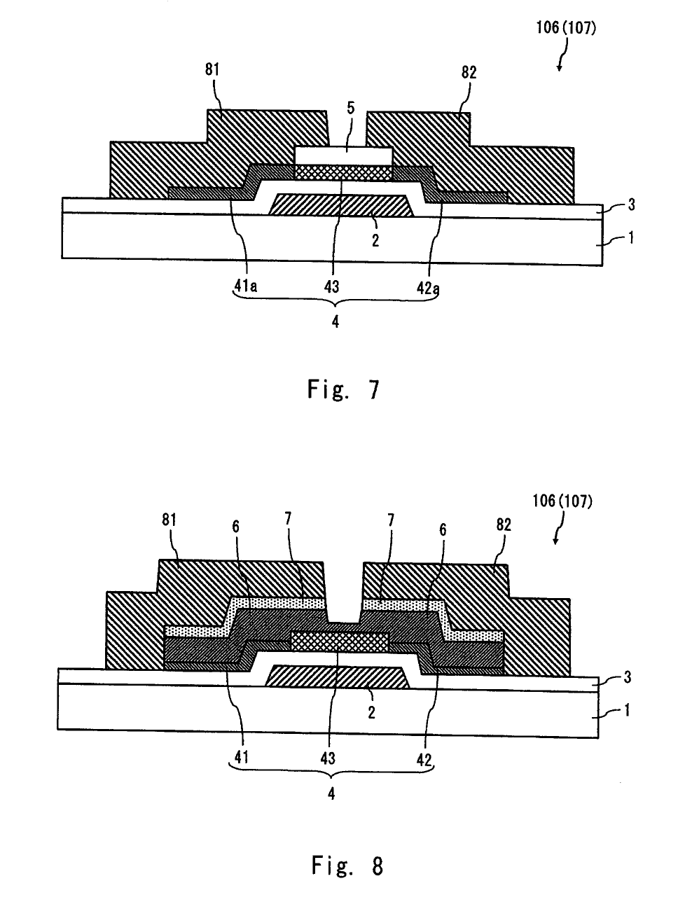

A structure of a microcrystalline TFT according to a third exemplary embodiment is described hereinafter with reference to FIG. 8. FIG. 8 is a cross-sectional view showing the structure of the microcrystalline TFT according to the third exemplary embodiment. In the third exemplary embodiment, the structure of the microcrystalline TFT is different from that of the first exemplary embodiment, and the other elements are the same as those of the first exemplary embodiment and thus not redundantly described.

The gate electrode 2 is disposed on the substrate 1, and the gate insulating film 3 is disposed to cover the gate electrode 2, as in the first exemplary embodiment. The semiconductor film 4 is disposed on the gate insulating film 3. Although the semiconductor film 4 is composed of the first amorphous region 41, the second amorphous region 42 and the crystalline region 43 as in the first exemplary embodiment, the first amorphous region 41 and the second amorphous region 42 are thinner than the crystalline region 43 in the third exemplary embodiment. In this example, the crystalline region 43 with a thickness of about 50 nm, and the first amorphous region 41 and the second amorphous region 42 with a thickness of about 40 nm are formed.

Further, in the third exemplary embodiment, although the translucent insulating film 5 may be provided on the crystalline region 43, the translucent insulating film 5 may be eliminated as shown in FIG. 8. Then, the amorphous semiconductor layer 6 is disposed on the semiconductor film 4. The amorphous semiconductor layer 6 is disposed substantially all over the semiconductor film 4. Specifically, although two patterns of the amorphous semiconductor layers 6 are placed on the semiconductor film 4 in the first exemplary embodiment, they are not separated and formed as one continuous pattern in the third exemplary embodiment. When the translucent insulating film 5 is not provided, the amorphous semiconductor layer 6 is disposed not only on the first amorphous region 41 and the second amorphous region 42 but also on the crystalline region 43 as shown in FIG. 8.

The ohmic contact layer 7 is disposed on the amorphous semiconductor layer 6. In the third exemplary embodiment, two patterns of ohmic contact layers 7 separated from each other are provided on one pattern of the amorphous semiconductor layer 6 disposed on the semiconductor film 4. Then, the source electrode 81 and the drain electrode 82 are disposed on the ohmic contact layers 7 as in the first exemplary embodiment.

To fabricate the microcrystalline TFT in such a structure, after performing laser annealing, the translucent insulating film 5 is etched entirely or partially, before depositing the amorphous semiconductor film 6a. For example, dilute hydrofluoric acid treatment with a concentration of 1% is performed for about three minutes. The part of the translucent insulating film 5 which is damaged by the laser light L can be thereby removed. Preferably, the translucent insulating film 5 is removed completely by the etching, and the vicinity of the top surface of the crystalline region 43 placed thereunder is removed. The surface of the crystalline region 43 contains many crystal defects caused by the laser annealing. Therefore, by removing the crystalline region 43 to some decree in the etching of the translucent insulating film 5, the defect level which hinders the on-current from flowing is reduced as in the second exemplary embodiment, so that more favorable TFT characteristics can be obtained.

Note that although the amorphous semiconductor film 4a which is exposed at the surface is etched at the same time as etching of the translucent insulating film 5, the amorphous semiconductor film 4a is not completely removed because an etching rate is about ⅙ of the translucent insulating film 5 when using the SiN film. For example, the thickness of the amorphous semiconductor film 4a is reduced to about 40 nm by the etching of the translucent insulating film 5.

After that, the amorphous semiconductor film 6a and the amorphous semiconductor film 7a containing an impurity are formed in this order, and, the laminated film composed of the amorphous semiconductor film 7a containing an impurity, the amorphous semiconductor film 6a, and the amorphous semiconductor film 4a is patterned into an island shape which is separated to respective TFTs, as in the first exemplary embodiment. Then, the source electrode 81 and the drain electrode 82 are placed on the patterned island-shaped laminated film, as in the first exemplary embodiment.

Then, by using the source electrode 81 and the drain electrode 82 as a mask, a part of the amorphous semiconductor film 7a containing an impurity placed above the crystalline region 43 is etched away, and further the amorphous semiconductor film 6a placed under the amorphous semiconductor film 7a containing an impurity is etched away partially in the thickness direction. The amorphous semiconductor film 7a containing an impurity is thereby separated, and two ohmic contact layers 7 separated from each other are formed. In this manner, the ohmic contact layer 7 is separated after forming the source electrode 81 and the drain electrode 82 and using them as a mask. This method is called back-channel etching.

As described above, according to the third exemplary embodiment, by adding the etching process of the translucent insulating film 5, the translucent insulating film 5 which is damaged by irradiation of the laser light L and the vicinity of the top surface of the crystalline region 43 containing many crystal defects can be removed. It is thereby possible to effectively reduce the defect level which hinders the on-current from flowing compared to the microcrystalline TFT according to the first exemplary embodiment. Therefore, more favorable TFT characteristics can be obtained. Further, because the source electrode 81 and the drain electrode 82 are formed above the semiconductor film 4 with the amorphous semiconductor layer 6 and the ohmic contact layer 7 interposed therebetween, the source electrode 81 and the drain electrode 82 are not in direct contact with the crystalline region 43. Thus, same advantageous effects as the first exemplary embodiment, which is reduction of the off-current, can be exerted.

Note that the same advantageous effects can be obtained if the source electrode 81 and the drain electrode 82 are electrically connected to the first amorphous region 41 and the second amorphous region 42 without direct contact with the crystalline region 43, and various structures may be applied without departing form the scope of the invention. For example, a contact hole that provides an opening for the first amorphous region 41 and the second amorphous region 42 may be formed in an insulating film that covers the semiconductor film 4, and the source electrode 81 and the drain electrode 82 may be connected to the first amorphous region 41 and the second amorphous region 42, respectively, through the contact hole without direct contact with the crystalline region 43.

The present invention is not limited to the above-described exemplary embodiments, and various changes and modifications may be made without departing from the scope of the invention. For example, although the case where the microcrystalline TFT according to the present invention is applied to the liquid crystal display device is described in the above exemplary embodiments, the present invention is not limited thereto. For example, a display device using a display material different from liquid crystals, such as an organic EL or an electronic paper, may be used. Further, the microcrystalline TFT according to the present invention may be suitably applied not only to a display device but also to another device such as a semiconductor device.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A thin film transistor comprising:
a gate electrode formed in one major plane of a substrate;
a gate insulating film covering the gate electrode;
a semiconductor film formed opposite to the gate electrode with the gate insulating film interposed and including a first amorphous region to serve as a source region, a second amorphous region to serve as a drain region, and a crystalline region to serve as a channel region disposed between the first amorphous region and the second amorphous region;
a source electrode formed above the semiconductor film without direct contact with the crystalline region and electrically connected to the source region; and
a drain electrode formed above the semiconductor film without direct contact with the crystalline region and electrically connected to the drain region.

2. The thin film transistor according to claim 1, further comprising:
a translucent insulating film formed on the crystalline region of the semiconductor film;
an amorphous semiconductor layer formed in each of a region from on the first amorphous region and to partly on the translucent insulating film and a region from on the second amorphous region to partly on the translucent insulating film; and
an ohmic contact layer formed between the source electrode and the amorphous semiconductor layer and between the drain electrode and the amorphous semiconductor layer.

3. The thin film transistor according to claim 1, further comprising:
a translucent insulating film formed on the crystalline region of the semiconductor film, wherein
the source electrode and the drain electrode are directly formed on the first amorphous region and the second amorphous region, respectively, and
each of the first amorphous region and the second amorphous region contains an impurity.

4. The thin film transistor according to claim 2, wherein the crystalline region of the semiconductor film is formed only under the translucent insulating film.

5. The thin film transistor according to claim 3, wherein the crystalline region of the semiconductor film is formed only under the translucent insulating film.

6. The thin film transistor according to claim 1, further comprising:
an amorphous semiconductor layer formed on the semiconductor film; and
an ohmic contact layer formed between the source electrode and the amorphous semiconductor layer and between the drain electrode and the amorphous semiconductor layer.

7. The thin film transistor according to claim 1, wherein the source electrode is formed in contact with an end face of the first amorphous region, and the drain electrode is formed in contact with an end face of the second amorphous region.

8. The thin film transistor according to claim 1, wherein the gate insulating film includes an oxide film formed at least in a part in contact with the semiconductor film.

9. A crystallization method of an amorphous semiconductor film comprising steps of:
depositing an amorphous semiconductor film in one major plane of a substrate;
forming a translucent insulating film of a given shape on the amorphous semiconductor film; and
performing laser annealing that irradiates the amorphous semiconductor film with laser light, allowing the laser light to be absorbed into the amorphous semiconductor film through the translucent insulating film, and crystallizing a part of the amorphous semiconductor film under the translucent insulating film.

10. The crystallization method of an amorphous semiconductor film according to claim 9, wherein an irradiation energy density of the laser light in the laser annealing is higher than a condition where the part of the amorphous semiconductor film under the translucent insulating film is converted into a microcrystalline semiconductor film having microcrystals with a crystal grain diameter of 100 nm or less by the laser light absorbed into the amorphous semiconductor film through the translucent insulating film, and lower than a condition where a part of the amorphous semiconductor film on which the translucent insulating film is not stacked is crystallized by the laser light absorbed into the amorphous semiconductor film directly without through the translucent insulating film.

11. A manufacturing method of a thin film transistor comprising steps of:
forming a gate electrode of a given shape in one major plane of a substrate;
forming a gate insulating film covering the gate electrode;
forming an amorphous first semiconductor film on the gate insulating film;
forming a translucent insulating film of a given shape on the first semiconductor film;
performing laser annealing that irradiates the first semiconductor film with laser light, allowing the laser light to be absorbed into the first semiconductor film through the translucent insulating film, and crystallizing a part of the first semiconductor film under the translucent insulating film; and
patterning the first semiconductor film into a shape including a crystalline region crystallized by the laser annealing and amorphous regions placed opposite to each other with the crystalline region placed therebetween.

12. The manufacturing method of a thin film transistor according to claim 11, wherein an irradiation energy density of the laser light in the laser annealing is higher than a condition where the part of the first semiconductor film under the translucent insulating film is converted into a microcrystalline semiconductor film having microcrystals with a crystal grain diameter of 100 nm or less by the laser light absorbed into the first semiconductor film through the translucent insulating film, and satisfies a condition where a part of the first semiconductor film on which the translucent insulating film is not stacked maintains an amorphous state by the laser light absorbed into the first semiconductor film directly without through the translucent insulating film.

13. The manufacturing method of a thin film transistor according to claim 11, wherein the gate insulating film is formed to include an oxide film at least in a part in contact with the first semiconductor film.

14. The manufacturing method of a thin film transistor according to claim 11, further comprising:
forming an amorphous second semiconductor film and an amorphous third semiconductor film containing an impurity in this order on the first semiconductor film to cover the translucent insulating film after the laser annealing;
forming a source electrode and a drain electrode on the third semiconductor film; and
etching away the third semiconductor film and the second semiconductor film on the translucent insulating film by using the source electrode and the drain electrode as a mask and using the translucent insulating film as an etching stopper.

15. The manufacturing method of a thin film transistor according to claim 11, further comprising:
implanting an impurity into the first semiconductor film by using the translucent insulating film as a mask after forming the translucent insulating film and before the laser annealing; and
forming a source electrode and a drain electrode on the first semiconductor film after the laser annealing.

16. The manufacturing method of a thin film transistor according to claim 11, further comprising:
etching the translucent insulating film after the laser annealing;
forming an amorphous second semiconductor film and an amorphous third semiconductor film containing an impurity in this order on the first semiconductor film after etching the translucent insulating film;
forming a source electrode and a drain electrode on the third semiconductor film;
etching the third semiconductor film by using the source electrode and the drain electrode as a mask, and
partially etching the second semiconductor film in a thickness direction by using the source electrode and the drain electrode as a mask.
